(19) United States
(12) Patent Application Publication
(10) Pub. No.: US 2008/0179615 A1
(43) Pub. Date: Jul. 31, 2008

(54) LIGHT-EMITTING DIODE DEVICE

(76) Inventors: Chi-Hung KAO, Taoyuan Hsien (TW); Horng-Jou Wang, Taoyuan Hsien (TW); Huang-Kun Chen, Taoyuan Hsien (TW)

Correspondence Address: BIRCH STEWART KOLASCH & BIRCH, PO BOX 747, FALLS CHURCH, VA, 22040-0747, US

(21) Appl. No.: 11/955,983

(22) Filed: Dec. 13, 2007

(30) Foreign Application Priority Data
Jan. 26, 2007 (TW) 096103006
Jan. 26, 2007 (TW) 096103007
Jan. 26, 2007 (TW) 096103008

(51) Int. Cl. H01L 33/00

(52) U.S. Cl. 257/98; 257/E33.067

(57) ABSTRACT

A light-emitting diode (LED) device includes a substrate, at least one LED element and an optical modulation structure. The LED element is disposed on the substrate and generates a light beam. The optical modulation structure is disposed at one side of the LED element for adjusting a shape of an optical field of the light beam and an intensity distribution of the optical field. The optical modulation structure is formed with a plurality of stepped protrusions.

### CROSS REFERENCE TO RELATED APPLICATIONS

This Non-provisional application claims priority under 35 U.S.C. §119(a) on Patent Application No(s). 096103006, 096103007 and 096103008, and all filed in Taiwan, Republic of China on Jan. 26, 2007, the entire contents of which are hereby incorporated by reference.

### BACKGROUND OF THE INVENTION

1. Field of Invention

The present invention relates to an electroluminescence light device and, in particular to a light-emitting diode (LED) device.

2. Related Art

A light-emitting diode (LED) is a cold light emitting element, which releases energy, which is generated when electrons and holes in a semiconductor material are combined, in the form of light. The LEDs with different materials can output the monochromatic light with different wavelengths. The LEDs are mainly divided into a visible light LED and an invisible light (infrared) LED. Compared with the light emitting manner of the conventional lamp or light bulb, the LED has the advantages of the power-saving property, the vibration resistant property and the higher flicker speed, and thus becomes an indispensable element in the daily life.

FIG. 1 is a schematic illustration showing a conventional LED device 1. As shown in FIG. 1, the conventional LED device 1 is constituted by one LED element 10 which is adhered to a transparent substrate 11. The LED element 10 is constituted by an n-type semiconductor layer 101, an electroluminescent layer 102 and a p-type semiconductor layer 103, all of which are sequentially arranged. A first contact electrode 104 is connected to the n-type semiconductor layer 101, and a second contact electrode 105 is connected to the p-type semiconductor layer 103. When voltages are to be applied to the n-type semiconductor layer 101 and the p-type semiconductor layer 103 to generate currents, the electrons and the holes in the n-type semiconductor layer 101 and the p-type semiconductor layer 103 are combined together so that the electrical energy is transformed into the optical energy.

FIG. 2A is a schematic illustration showing an optical field of the LED device of FIG. 1. The LED device 1 uses a lens 12 having a semi-circular body for converging the light beam emitted from the LED element 10. That is, the light emitting direction is converged around an optical axis OS1. So, the LED device 1 is only suitable for the illumination equipments with a small angle and concentrated energy, such as a flashlight, a table lamp or a traffic sign. FIG. 2B is a schematic illustration showing a light guide plate and the LED device of FIG. 2A. When the LED device 1 is applied to a side-lighting backlight module of a display panel, a light guide plate 6 is usually needed to enhance the uniformity of the light beam. However, the attenuation of the light beam laterally entering the light guide plate 6 is increased with the increased distance to the lighting source, thereby limiting the light emitting area of the display panel.

FIG. 3A is a schematic illustration showing another conventional LED device 2. As shown in FIG. 3A, a lens body 22 applied to the LED device 2 is combined with a substrate 21 to package a LED element 20. A surface of the lens body 22 neighboring a circumference of an optical axis OS2 has a concave section C to form a diverging surface for refracting and diverging the converged light beam around the optical axis OS2 away from the optical axis OS2. Thus, the LED device 2 can provide a uniform and large light emitting area, and can be directly applied to the backlight module without the provision of the light guide plate. FIG. 3B is a schematic illustration showing a shape of an optical field of the LED device of FIG. 3A. As shown in FIG. 3B, however, the lens body 22 is a circular symmetrical structure, so the light emitting area A also has a circular symmetrical shape. When there are several LED devices 2 simultaneously arranged to serve as the backlight source of the backlight module, the light emitting areas A of each two neighboring LED devices 2 overlap with each other, thereby causing non-uniform of the light emitting intensity.

### SUMMARY OF THE INVENTION

In view of the foregoing, the present invention is to provide a LED device capable of adjusting a shape of an optical field and an intensity distribution of the optical field.

To achieve the above, the present invention discloses a LED device including a substrate, at least one LED element and an optical modulation structure. The LED element is disposed on the substrate and generates a light beam. The optical modulation structure is disposed at one side of the LED element for adjusting a shape of an optical field and an intensity distribution of the optical field. The optical modulation structure is formed with a plurality of stepped protrusions.

As mentioned above, an optical modulation structure of the LED device according to the present invention is utilized to adjust the phase or direction of the optical field of the light beam outputted from the LED element so that the function of changing the shape of the optical field of the light beam and the intensity distribution of the optical field of the light beam can be achieved and the light emitting areas of the LED elements cannot overlap with one another. Thus, the non-uniform of the light emitting intensity in the prior art can be effectively improved. The optical modulation structure is disposed on a light outputting surface of the LED element. That is, the optical modulation structure can be disposed at one side of the LED element or one side of the substrate. In addition, the structure design of the optical modulation structure can also prevent the light beams from being converged around the optical axis so that the light emitting area can be homogenized.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic illustration showing a conventional LED device;

FIG. 2A is a schematic illustration showing an optical field of the LED device of FIG. 1;

FIG. 2B is a schematic illustration showing the LED device of FIG. 2A and a light guide plate;

FIG. 3A is a schematic illustration showing another conventional LED device;

FIG. 3B is a schematic illustration showing a shape of an optical field of the LED device of FIG. 3A;

FIGS. 4A and 4E are schematic illustrations showing two LED devices according to a first embodiment of the present invention;

FIGS. 4B to 4D are schematically cross-sectional views showing various protrusions corresponding to a dashed-line circular portion of FIG. 4A;

FIG. 5 is a schematic illustration showing a shape of an optical field of the LED device according to the first embodiment of the present invention;

FIGS. 6A and 6B are schematic illustrations showing two LED devices according to a second embodiment of the present invention;

FIGS. 7A and 7B are schematic illustrations showing two LED devices according to a third embodiment of the present invention; and

FIG. 8 is a schematic illustration showing a LED device according to a fourth embodiment of the present invention.

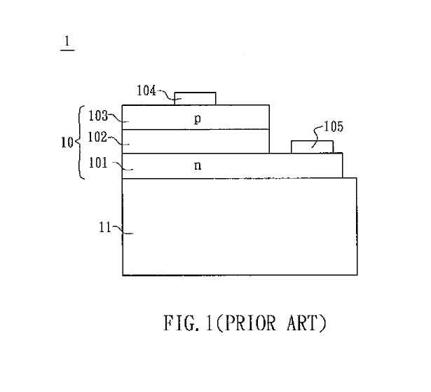

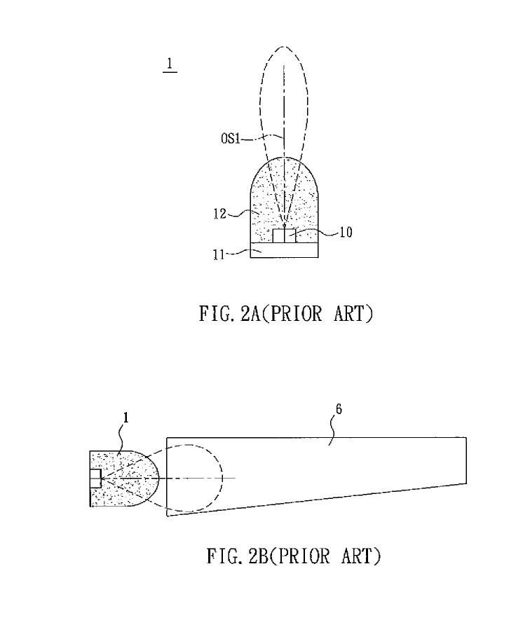

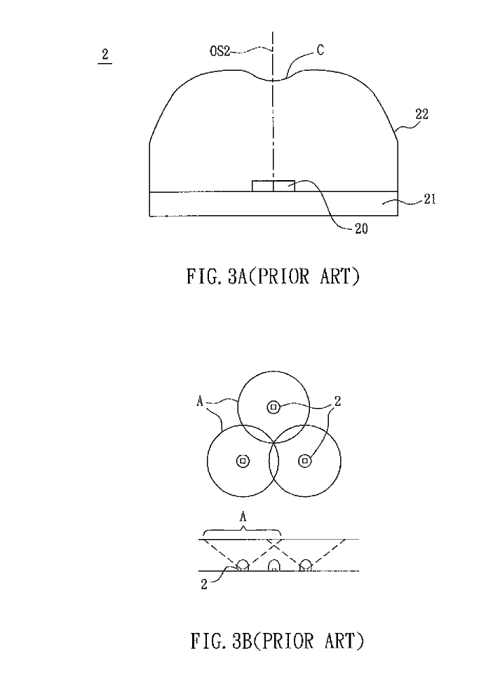

### DETAILED DESCRIPTION OF THE INVENTION

The present invention will be apparent from the following detailed description, which proceeds with reference to the accompanying drawings, wherein the same references relate to the same elements.

### THE FIRST EMBODIMENT

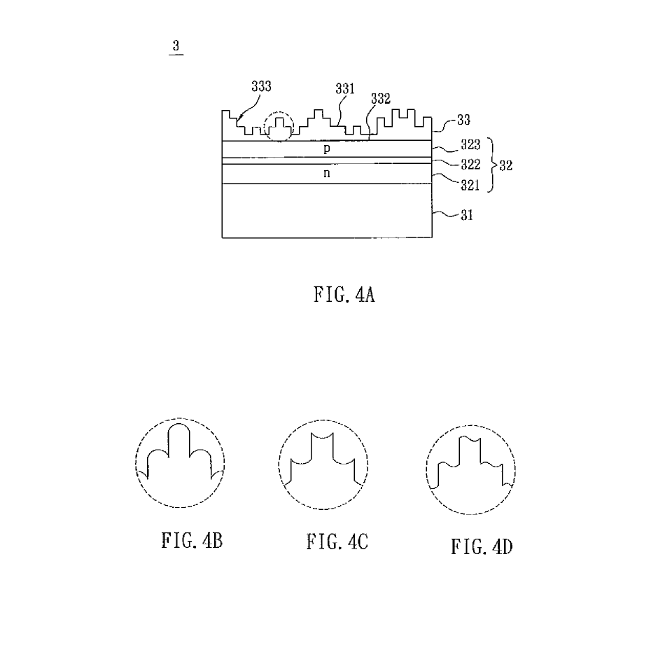

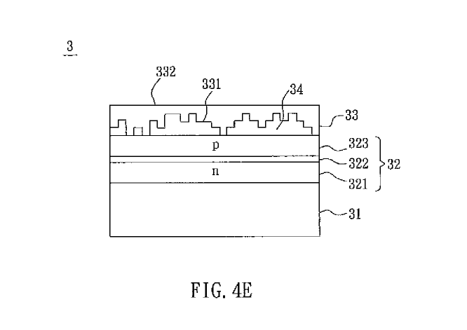

Referring to FIGS. 4A and 4B, which show a LED device according to a first embodiment. The LED device 3 according to the first embodiment of the present invention includes a substrate 31, at least one LED element 32 and an optical modulation structure 33.

The LED element 32 is disposed on the substrate 31. In this embodiment, the substrate 31 is an epitaxy substrate, and the LED element 32 sequentially includes a first semiconductor layer 321, an electroluminescent layer 322 and a second semiconductor layer 323. The first semiconductor layer 321 is disposed on the substrate 31, and the electroluminescent layer 322 is disposed between the first semiconductor layer 321 and the second semiconductor layer 323. In addition, the LED device 3 of this embodiment further includes an electrode pair including a first contact electrode and a second contact electrode respectively connected to the first semiconductor layer 321 and the second semiconductor layer 323 (not shown). When voltages are applied to the first semiconductor layer 321 and the second semiconductor layer 323 through the first contact electrode and the second contact electrode to generate currents, respectively, electrons and holes of the first semiconductor layer 321 and the second semiconductor layer 323 are combined together in the electroluminescent layer 322 to release the energy transformed into a light beam.

In this embodiment the first semiconductor layer 321 can be an n-type semiconductor layer and the second semiconductor layer 323 can be a p-type semiconductor layer. However, this is only for the illustrative purpose. Of course, the first semiconductor layer 321 can be a p-type semiconductor layer and the second semiconductor layer 323 can be an n-type semiconductor layer according to the actual requirement.

The optical modulation structure 33 is disposed at one side of the LED element 32. In this embodiment, the optical modulation structure 33 is disposed on a light outputting surface of the LED device 3, as shown in FIGS. 4A and 4E, and the optical modulation structure 33 is disposed on the LED element 32. FIG. 4E is a schematic illustrations showing another LED device according to a first embodiment of the present invention. In addition, the optical modulation structure 33 for adjusting the light beam outputted from the LED element 32 can also be disposed on a lateral side (not shown) of the LED element 32.

In this embodiment, the optical modulation structure 33 can be a binary optical device, which has a first surface 331 and a second surface 332 disposed opposite to the first surface 331, as shown in FIG. 4A. The first surface 331 has a plurality of stepped protrusions 333, such as binary optical protrusions, each having a flat surface. The stepped protrusions 333 are arranged in a symmetrical manner, a non-symmetrical manner or an irregular manner, wherein the symmetrical manner means that the stepped protrusions are arranged symmetrically with respect to an optical axis of the light beam. In this embodiment, each stepped protrusion 333 has a micro-structure, which has a 2-level structure, wherein n is a positive integer. The second surface 332 of the optical modulation structure 33 faces the LED element 32 and is connected to the second semiconductor layer 323.

In this embodiment the optical modulation structure 33 is made of a light-permeable material, which is epoxy resin, optical glass, semiconductor, indium tin oxide (ITO), cadmium tin oxide, antimony tin oxide or combinations thereof, wherein the semiconductor can pertain to the group III-V, group II-VI or group IV.

However, the present invention is not limited thereto. For example, in addition to the binary optical protrusion having the flat surface, each of the stepped protrusions 333 can also have a curved surface, a convex cross-section (see FIG. 4B), a concave cross-section (see FIG. 4C), a wavy cross-section (see FIG. 4D) or any other shape. Also, for the sake of clear illustration, FIGS. 4B to 4D only show the schematically cross-sectional views of various stepped protrusions in the dashed-line circular portion of FIG. 4A. In practice, however, all types of the stepped protrusions 333 on the first surface 331 of the optical modulation structure 33 of the LED device 3 can be applied.

In addition, as shown in FIG. 4E, the optical modulation structure 33 of this embodiment can also be disposed with the first surface 331 facing the LED element 32 and being partially connected to the second semiconductor layer 323. Herein, the LED device 3 of this embodiment further includes a transparent adhesive layer 34 for adhering the optical modulation structure 33 to the LED element 32. That is, the transparent adhesive layer 34 is disposed between the optical modulation structure 33 and the LED element 32. The material of the transparent adhesive layer 34 includes the epoxy resin.

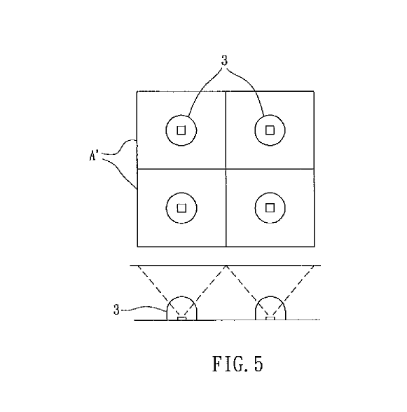

As mentioned hereinabove, the phase or the direction of the light beam outputted from the LED element 32 is adjusted by the stepped micro-structure of the optical modulation structure 33. Thus, the optical field of the light beam has the non-ordinary circular shape, and the shape of the optical field can become a triangular shape, a tetragonal shape or a polygonal shape according to the structure design. FIG. 5 is a schematic illustration showing a shape of an optical field of the LED device according to the first embodiment of the present invention. As shown in FIG. 5, the optical field has a square shape, and the light beams generated by the neighboring LED devices 3 can be configured such that the neighboring light emitting areas A′ cannot overlap and interfere with each other due to the adjustable shape of the optical field. Thus, the problem of the non-uniform light emitting intensity can be effectively improved.

In addition, the LED device of the first embodiment can further include a transparent conductive layer disposed between the LED element and the optical modulation structure to increase the diffusion efficiency of the current and thus enhance the light emitting efficiency of the LED device. The material of the transparent conductive layer can be indium tin oxide, cadmium tin oxide, antimony tin oxide or combinations thereof.

### THE SECOND EMBODIMENT

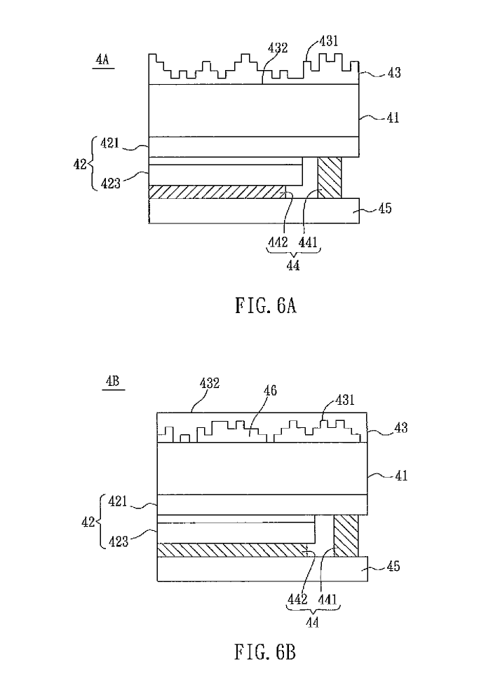

FIGS. 6A and 6B are schematic illustrations showing two LED devices according to a second embodiment of the present invention. Referring to FIGS. 6A and 6B, the LED device 4A or 4B includes a substrate 41, at least one LED element 42 and an optical modulation structure 43, which is disposed over the substrate 41. In this embodiment, the materials, structures and functions of the substrate 41, the LED element 42 and the optical modulation structure 43 are the same as those of the first embodiment mentioned hereinabove, so detailed descriptions thereof will be omitted.

The LED device 4A or 4B further includes an electrode pair 44, which includes a first contact electrode 441 and a second contact electrode 442. The first contact electrode 441 is connected to a first semiconductor layer 421, while the second contact electrode 442 is connected to a second semiconductor layer 423.

The LED device 4A or 4B can be applied to a flip-chip type package. Herein, the LED device 4A or 4B further includes a heat dissipating substrate 45, and the LED element 42 is connected to the heat dissipating substrate 45 in a flip-chip manner, as shown in FIGS. 6A and 6B. The first contact electrode 441 and the second contact electrode 442 connected to the LED element 42 are disposed between the LED element 42 and the heat dissipating substrate 45.

The optical modulation structure 43 is disposed at the other side of the substrate 41 and opposite to the LED element 42. That is, the optical modulation structure 43 is disposed on a light outputting surface of the flip-chip type LED device 4, and the optical modulation structure 43 of this embodiment is the same as that described hereinabove. A second surface 432 of the optical modulation structure 43 can face the substrate 41 and be connected thereto, as shown in FIG. 6A. Also, a first surface 431 of the optical modulation structure 43 can face the substrate 41 and be adhered thereon, as shown in FIG. 6B. This can be implemented by a transparent adhesive layer 46 disposed between the optical modulation structure 43 and the substrate 41.

### THE THIRD EMBODIMENT

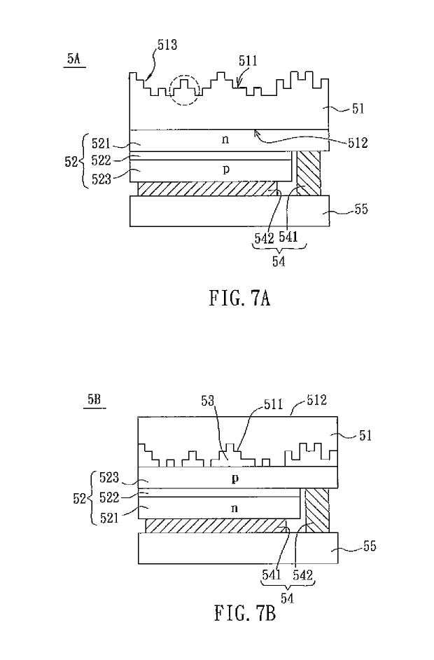

FIGS. 7A and 7B are schematic illustrations showing two LED devices according to a third embodiment of the present invention. The LED device 5A or 5B includes a substrate 51 and at least one LED element 52. In this embodiment, the substrate 51 has the function as the previously mentioned optical modulation structure for adjusting a shape of an optical field and an intensity distribution of the optical field. In other words, the substrate 51 of this embodiment is composed of the substrate 31 and the optical modulation structure 33, which are integrally formed as a single unit.

In this embodiment, the substrate 51 can be a light-permeable substrate made of a material, which is epoxy resin, optical glass, semiconductor or combinations thereof, wherein the semiconductor can pertain to the group III-V, the group II-VI or the group IV. In addition, the substrate 51 can also be a general epitaxy substrate made of the material comprising silicon carbide or aluminum oxide, such as Al₂O₃.

The substrate 51 has a first surface 511 and a second surface 512 opposite to the first surface 511. The first surface 511 has a plurality of stepped protrusions 513. In this embodiment, the stepped protrusions 513 are binary optical protrusions each having a flat surface, and are arranged in a symmetrical manner, in a non-symmetrical manner or an irregular manner, wherein the symmetrical manner means that the stepped protrusions are arranged symmetrically with respect to an optical axis of the light beam. In this embodiment, each stepped protrusion 513 has a micro-structure, which has a 2ⁿ-level structure, wherein n is a positive integer.

As shown in FIG. 7A, the LED element 52 is disposed at one side of the substrate 51. In this embodiment the LED element 52 is connected to the second surface 512 of the substrate 51, the LED element 52 includes a first semiconductor layer 521, an electroluminescent layer 522 and a second semiconductor layer 523, and the second semiconductor layer 523, the electroluminescent layer 522 and the first semiconductor layer 521 are sequentially disposed at the second surface 512 of the substrate 51. In this embodiment, the first semiconductor layer 521 can be an n-type semiconductor layer, and the second semiconductor layer 523 can be a p-type semiconductor layer. However, this is only for the illustrative purpose. Of course, the first semiconductor layer 521 can be a p-type semiconductor layer, and the second semiconductor layer 523 can be an n-type semiconductor layer according to the actual requirement.

FIG. 7B is a schematic illustration showing another LED device 5B according to the third embodiment of the invention. As shown in FIG. 7B, the LED element 52 of this embodiment can also be connected to the first surface 511 of the substrate 51. That is, the LED element 52 is adhered to and faces the first surface 511 of the substrate 51. Herein, the LED device 5B of this embodiment further includes a light-permeable adhesive layer 53 adhering the substrate 51 to the LED element 52. That is, the light-permeable adhesive layer 53 is disposed between the substrate 51 and the LED element 52, wherein the material of the light-permeable adhesive layer 53 includes the epoxy resin.

As shown in FIGS. 7A and 7B, the LED device 5A or 5B can further include an electrode pair 54, which includes a first contact electrode 541 and a second contact electrode 542 respectively connected to the first semiconductor layer 521 and the second semiconductor layer 523. When voltages are applied to the first semiconductor layer 521 and the second semiconductor layer 523 through the first contact electrode 541 and the second contact electrode 542 to generate currents, respectively, electrons and holes in the first semiconductor layer 521 and the second semiconductor layer 523 are combined together in the electroluminescent layer 522, and the energy released after the electrons and the holes are combined together is transformed into the light beam, which emits toward the substrate 51. The stepped micro-structure of the stepped protrusions 513 can adjust the phase or direction of the light beam so that the shape of the optical field of the light beam becomes a non-ordinary circular shape. Thus, the shape of the optical field can become a triangular shape, a tetragonal shape or a polygonal shape according to the structure. In this embodiment, the optical field has a square shape, and the neighboring LED devices 5 generate a plurality of light beams. Because the shape of the optical field is adjustable, the neighboring light emitting areas can be configured such that they do not overlap and interfere with each other. Thus, the problem of the non-uniform light emitting intensity can be effectively improved and the functions of shaping the light beam and adjusting the intensity distribution of the optical field can be obtained.

In addition, the LED device 5A or 5B further include a light-permeable conductive layer, which is disposed between the LED element 52 and the substrate 51 (not shown), and is for enhancing the diffusion efficiency of the current to increase the light emitting efficiency of the LED device 5. The material of the transparent conductive layer can be indium tin oxide, cadmium tin oxide, antimony tin oxide or combinations thereof.

In this embodiment, as shown in FIGS. 7A and 7B, the LED device 5A or 5B can be applied to a flip-chip type package structure. Herein, the LED device 5 further includes a heat dissipating substrate 55, and the LED element 52 is connected to the heat dissipating substrate 55 in a flip-chip manner. The first contact electrode 541 and the second contact electrode 542 connected to the LED element 52 are disposed between the LED element 52 and the heat dissipating substrate 55.

### THE FOURTH EMBODIMENT

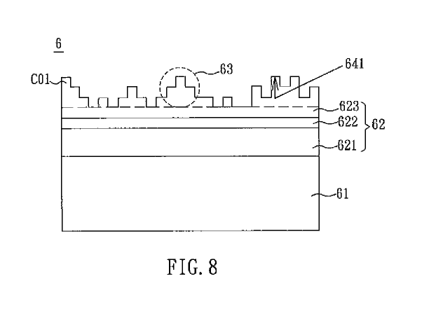

Referring to FIG. 8, which is a schematic illustration showing a LED device according to a fourth embodiment of the present invention. A LED device 6 includes a substrate 61, at least one LED element 62 and an optical modulation structure 63.

In this embodiment, the substrate 61 is a thermal-conducting substrate, which is made of silicon, gallium arsenide, gallium phosphide, silicon carbide, boron nitride, aluminum, aluminum nitride, copper or combinations thereof.

The LED element 62 includes a first semiconductor layer 621, an electroluminescent layer 622 and a second semiconductor layer 623. The first semiconductor layer 621 is formed on the substrate 61. The electroluminescent layer 622 is formed on the first semiconductor layer 621, and the electroluminescent layer 622 generates a light beam. The second semiconductor layer 623 is formed on the electroluminescent layer 622, and a light outputting surface 641 of the second semiconductor layer 623 is formed with the optical modulation structure 63, i.e. a plurality of stepped protrusions C01. The light beam generated by the electroluminescent layer 63 travels to the light outputting surface 641 of the second semiconductor layer 623. In this embodiment, the second semiconductor layer 623 has the function as the previously mentioned optical modulation structure for adjusting a shape of an optical field and an intensity distribution of the optical field. In other words, the second semiconductor layer 623 and the optical modulation structure 63 are combined and integrally formed as a single unit.

In this embodiment, the first semiconductor layer 621 can be a p-type doped layer while the second semiconductor layer 623 can be an n-type doped layer. Of course, the first semiconductor layer 621 can also be an n-type doped layer while the second semiconductor layer 623 can also be a p-type doped layer without any limitative purpose.

According to different shapes and intensities of optical fields, the stepped protrusions C01 of the second semiconductor layer 623 can be arranged in an axially symmetrical manner, a non-axially symmetrical manner or an irregular manner. Herein, the stepped protrusions C01 are arranged in the irregular manner. In addition, the formed stepped protrusions C01 in this embodiment are binary optical protrusions, each of which has a flat surface. Also, the stepped protrusions C01 have 2^{N} steps, wherein N is a positive integer, such as 1, 2, 3, and the like.

In summary, an optical modulation structure of the LED device according to the present invention is utilized to adjust the phase or direction of the optical field of the light beam outputted from the LED element so that the function of changing the shape of the optical field of the light beam and the intensity distribution of the optical field of the light beam can be achieved and the light emitting areas of the LED elements cannot overlap with one another. Thus, non-uniform of the light emitting intensity in the prior art can be effectively improved. The optical modulation structure is disposed on a light outputting surface of the LED element. That is, the optical modulation structure can be disposed at one side of the LED element or one side of the substrate. In addition, the structure design of the optical modulation structure can also prevent light beams from being converged around the optical axis so that the light emitting area can be homogenized. In addition to the stepped protrusions of the optical modulation structure, a suitable lens can be disposed on the light-emitting path. That is, the lens is disposed between the optical modulation structure and the object illuminated by the light beam so that the optical property of the light beam is adjusted and the application range of the present invention can become wider.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting diode (LED) device, comprising:
a substrate;
at least one LED element disposed on the substrate for generating a light beam; and
an optical modulation structure disposed at one side of the LED element for adjusting a shape of an optical field of the light beam and an intensity distribution of the optical field, wherein the optical modulation structure is formed with a plurality of stepped protrusions.

2. The LED device according to claim 1, wherein the optical modulation structure is a binary optical device.

3. The LED device according to claim 1, wherein the stepped protrusions are arranged in an axially symmetrical manner, a non-axially symmetrical manner or an irregular manner.

4. The LED device according to claim 1, wherein the stepped protrusions has 2ⁿ steps, and n is a positive integer.

5. The LED device according to claim 4, wherein each of the stepped protrusions is a binary optical protrusion.

6. The LED device according to claim 5, wherein each of the stepped protrusions has a flat surface.

7. The LED device according to claim 1, wherein each of the stepped protrusions has a curved surface.

8. The LED device according to claim 1, wherein the optical modulation structure comprises a light-permeable material.

9. The LED device according to claim 8, wherein the light-permeable material is epoxy resin, optical glass, semiconductor, indium tin oxide (ITO), cadmium tin oxide, antimony tin oxide or combinations thereof.

10. The LED device according to claim 1, wherein the optical modulation structure is disposed over the substrate.

11. The LED device according to claim 1, wherein the optical modulation structure and the substrate are integrally formed as a single unit.

12. The LED device according to claim 1, wherein the LED element comprises a first semiconductor layer, an electroluminescent layer and a second semiconductor layer, and the electroluminescent layer is disposed between the first semiconductor layer and the second semiconductor layer.

13. The LED device according to claim 12, further comprising:
an electrode pair, comprising a first contact electrode connected to the first semiconductor layer and a second contact electrode connected to the second semiconductor layer.

14. The LED device according to claim 12, wherein the optical modulation structure faces the LED element and is connected to the second semiconductor layer.

15. The LED device according to claim 12, wherein the optical modulation structure is disposed over the second semiconductor layer and is partially connected to the second semiconductor layer.

16. The LED device according to claim 12, wherein the optical modulation structure is disposed over the second semiconductor layer and is connected to the second semiconductor layer.

17. The LED device according to claim 16, further comprising:
a transparent adhesive layer for adhering the optical modulation structure to the LED element, wherein the transparent adhesive layer comprises epoxy resin.

18. The LED device according to claim 1, further comprising:
a transparent conductive layer disposed between the LED element and the optical modulation structure, wherein the transparent conductive layer comprises indium tin oxide, cadmium tin oxide, antimony tin oxide or combinations thereof.

19. The LED device according to claim 1, wherein the shape of the optical field is a triangular shape, a tetragonal shape or a polygonal shape.

20. The LED device according to claim 1, wherein a light-emitting path of the light beam is formed from the LED element to a to-be-illuminated object, and a lens for adjusting an optical property of the light beam is disposed on the light-emitting path.
